(19) United States
(12) Patent Application Publication
(10) Pub. No.: US 2005/0258470 A1
(43) Pub. Date: Nov. 24, 2005

(54) Gate stack of nanocrystal memory and method for forming same

(76) Inventors: Bohumil Lojek, Colorado Springs, CO (US); Philip O. Smith, Colorado Springs, CO (US)

Correspondence Address: SCHNECK & SCHNECK, P.O. BOX 2-E, SAN JOSE, CA, 95109-0005, US

(21) Appl. No.: 10/850,897

(22) Filed: May 20, 2004

(51) Int. Cl. H01L 29/788

(52) U.S. Cl. 257/315

(57) ABSTRACT

A nanocrystal memory gate stack and a method for forming same includes first forming a first thermal oxide layer on a surface of a substrate followed by forming a control layer dielectric over the first thermal oxide layer. The control layer dielectric contains a plurality of nanocrystals. A polycrystalline gate is formed over the control layer dielectric and portions of the control layer dielectric that are not covered by the polycrystalline gate are etched until a plurality of nanocrystals not located under the polycrystalline gate is exposed. The exposed plurality of nanocrystals is consumed by employing a thermal oxidation process. A remaining plurality of nanocrystals located under the polycrystalline gate forms a floating gate and the thermal oxidation process produces a second thermal oxide. The second thermal oxide layer is anisotropically etched to form oxide spacers surrounding the polycrystalline gate.

### TECHNICAL FIELD

A present invention described herein relates generally to a process for fabricating an integrated circuit structure, and more specifically to an electronic memory device employing nanocrystals and a process for fabrication thereof.

### BACKGROUND ART

Electrically erasable programmable read only memory (EEPROM) structures are commonly used in integrated circuits for non-volatile data storage. EEPROM device structures commonly include a floating gate that has charge storage capabilities. Charge can be forced into the floating gate structure or removed from the floating gate using control voltages. A conductivity of a channel underlying the floating gate is significantly altered by charges stored in the floating gate. A difference in charge stored in a charged or uncharged floating gate can be current sensed, thus allowing binary memory states to be determined.

As semiconductor devices continue to evolve, the operating voltages of the devices are typically reduced in order to suit low power applications. However, speed and functionality of the devices ordinarily must be maintained or improved with a concomitant reduction in voltage. One controlling factor in the operating voltages required to program and erase floating gate devices is a thickness of the tunnel oxide. Carriers are exchanged between the floating gate and the underlying channel region through the tunnel oxide.

In most prior art device structures, the floating gate is formed from a uniform layer of material, such as polysilicon. In these prior art device structures, a thin tunnel dielectric layer beneath the floating gate presents a potential problem of charge leakage from the floating gate to the underlying channel through defects in the thin tunnel dielectric layer. As tunnel oxides become thinner to reduce control voltage requirements, the potential charge leakage increases. Such charge leakage can lead to degradation of the memory state stored within the device.

In order to reduce the required thickness of the tunnel dielectric, thereby allowing lower control voltages, the uniform layer of material used for the floating gate may be replaced with a plurality of nanocrystals, which operate as isolated charge storage elements. In combination, a plurality of nanocrystals provide adequate charge storage capacity while remaining physically isolated from each other. Any leakage occurring with respect to a single nanocrystal through a local underlying defect does not cause charge to be drained from other nanocrystals. Lateral charge flow between nanocrystals in the floating gate can be ensured by controlling average spacing between nanocrystals by techniques known in the art. Therefore, thinner tunnel dielectrics can be used in device structures employing nanocrystals. Effects of leakage occurring in thin tunnel dielectric devices with nanocrystals does not cause the loss of state information that occurs in devices that include a uniform-layer floating gate.

Due to an increasing use in the use of nanocrystals in EEPROM and similar devices, it is desirable to develop a robust and efficient method of fabricating floating gate devices which employ nanocrystals.

### DISCLOSURE OF THE INVENTION

The present invention is a method for forming a nanocrystal memory gate stack. The nanocrystal memory gate stack includes first forming a first thermal oxide layer on a surface of a substrate, followed by nanocrystal deposition and forming a control layer dielectric over the first thermal oxide layer and nanocrystal layer. The control layer dielectric contains a plurality of nanocrystals. A polycrystalline gate is formed over the control layer dielectric. Portions of the control layer dielectric that are not covered by the polycrystalline gate are etched until a plurality of nanocrystals not located under the polycrystalline gate is exposed. The exposed plurality of nanocrystals is consumed by employing a thermal oxidation process. A remaining plurality of nanocrystals located under the polycrystalline gate forms a floating gate. The thermal oxidation process produces a second thermal oxide which overlies the polycrystalline gate. The second thermal oxide layer is anisotropically etched to form oxide spacers surrounding the polycrystalline gate.

The present invention is also an electronic memory device that includes a substrate (e.g., a portion of a silicon wafer) and a floating gate comprised of nanocrystals. The floating gate is formed by
(i) forming a control layer dielectric on a surface of a substrate, the control layer dielectric containing a plurality of nanocrystals;
(ii) forming a polycrystalline gate over the control layer dielectric;
(iii) etching portions of the control layer dielectric that are not covered by the polycrystalline gate until a plurality of nanocrystals that is not under the polycrystalline gate is exposed; and
(iv) consuming the exposed plurality of nanocrystals by employing a thermal oxidation process, a remaining plurality of nanocrystals forms the floating gate, and the thermal oxidation process produces a second thermal oxide.

The electronic memory device also includes a first thermal oxide layer. The first thermal oxide layer is configured to allow a transfer of electrons into the remaining plurality of nanocrystals. The remaining plurality of nanocrystals is separated from the substrate by the first thermal oxide layer. Finally, the electronic memory device has a control gate which is separated from the remaining plurality of nanocrystals in the floating gate by the control layer dielectric.

### BRIEF DESCRIPTION OF THE DRAWINGS

FIG. 1 is an exemplary embodiment of a nanocrystal memory gate stack.

FIG. 2 is the nanocrystal memory gate stack of FIG. 1 with an overcoat of photoresist.

FIG. 3 is the nanocrystal memory gate stack with photoresist layer of FIG. 2 after etching the photoresist layer and an uppermost layer of the gate stack.

FIG. 4 is the nanocrystal memory gate stack of FIG. 3 with exposed nanocrystals.

FIG. 5 is the nanocrystal memory gate stack with the exposed nanocrystals of FIG. 4 consumed by a thermal oxide.

FIG. 6 is the nanocrystal memory gate stack of FIG. 5 with oxide spacers and prepared for standard subsequent process steps.

### BEST MODE FOR CARRYING OUT THE INVENTION

With reference to FIG. 1, a base substrate 101 with shallow-trench isolation (STI) regions 103, and a film stack (described infra) provide a starting point for an exemplary nanocrystal memory gate of the present invention.

The base substrate 101 is frequently a silicon wafer. Alternatively, another elemental group IV semiconductor or compound semiconductor (e.g., groups III-V or II-VI) may be selected for base substrate 101.

A technique for fabricating STI regions 103 is known in the art and therefore will only be described briefly. The STI fabrication technique involves depositing and patterning a dielectric layer (not shown) deposited onto the base substrate 101. The patterned dielectric layer provides an etch mask for the base substrate 101. The base substrate 101 is then dry etched. The etched base substrate 101 forms a trench (not shown). A dielectric, typically oxide, is deposited (e.g., by a chemical vapor deposition (CVD) process), filling the trench. The trench fill material is then planarized (e.g., by a chemical mechanical planarization (CMP) process), leaving the trench fill material essentially co-planar with an uppermost surface of the base substrate 101. The resulting STI regions 103 electrically isolate subsequently implanted or diffused dopant regions.

The film stack includes a first thermal oxide layer 105, a control oxide layer 107 with embedded nanocrystals 109, and a gate polysilicon layer 111. In a specific exemplary embodiment, the first thermal oxide layer 105 is about 3 nm to 5 nm (i.e., 30 Å-50 Å) in thickness, the control oxide layer 107 is silicon dioxide about 6 nm to 10 nm (i.e., 60 Å-100 Å) in thickness, and the gate polysilicon layer 111 is about 150 nm (i.e., 1500 Å) thick. The various layers may be deposited or grown by various methods well known to one skilled in the art.

Various methods for forming the embedded nanocrystals 109 are known by one skilled in the art. For example, silicon atoms may be implanted into a dielectric material. A subsequent annealing step causes the implanted silicon atoms to group together through phase separation to form the nanocrystals. Alternatively, amorphous silicon may be deposited on top of a tunnel dielectric layer, followed by a subsequent annealing step to recrystalize the amorphous silicon into nanocrystals. Other techniques have focused on an LPCVD nucleation and growth process to form crystalline nanocrystals directly on a tunnel dielectric layer. Nanocrystals are typically from 3 nm to 6 nm (30 Å-60 Å) in size with a surface density of about 4 (10¹¹)/cm² to 10 (10¹¹)/cm², but other sizes and surface densities have been contemplated.

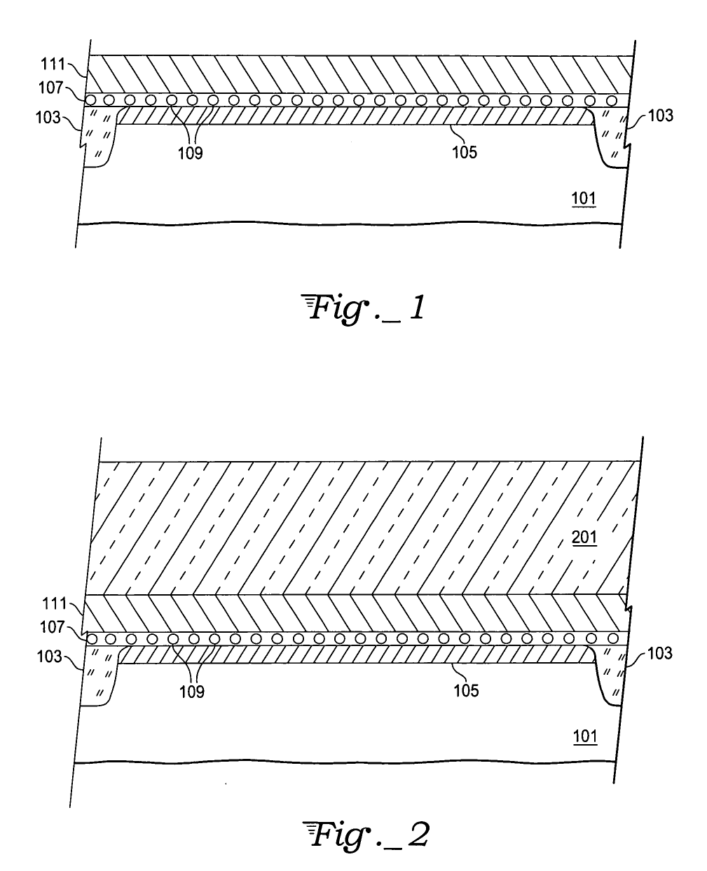

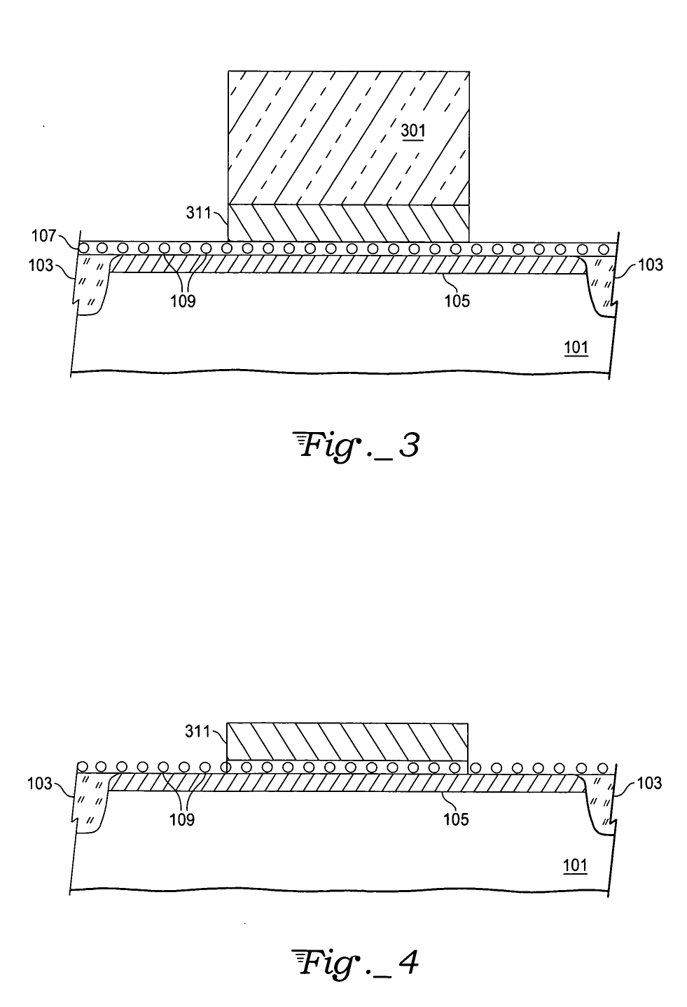

Referring to FIG. 2, a photoresist layer 201 is coated or otherwise deposited over the gate polysilicon layer 111. The photoresist layer 201 is then patterned, developed, and etched producing a photoresist etch mask 301 (FIG. 3) for the polysilicon gate layer 111. The polysilicon gate layer 111 is anisotropically etched (e.g., by a reactive ion etch (RIE)), down to the control oxide layer, thereby producing a polysilicon gate 311.

With reference to FIG. 4, the photoresist etch mask 301 is removed and the control oxide layer 107 is etched. Etching the control oxide layer 107 exposes the nanocrystals 109. In the case of silicon nanocrystals, a high selectivity SiO₂ to Si etchant etches the control oxide layer 107 while leaving the nanocrystals 109 intact. A specific exemplary etchant uses one of various fluorinated compounds (e.g., CF₄, CHF₃, or C₄F₈) in a low power plasma etcher to remove the control oxide layer 107. An endpoint detection scheme (e.g., based on the optical properties of silicon found in the nanocrystals) may be employed to insure that neither the control oxide layer 107 nor the nanocrystals 109 are over etched. Overetching has a potential risk of etching the first thermal oxide layer 105. Therefore, overetching is typically avoided.

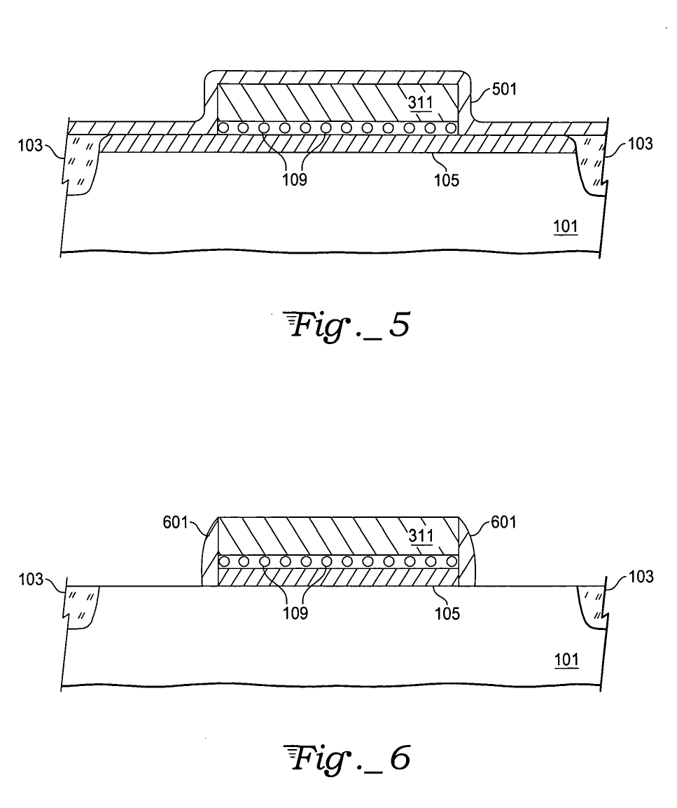

Referring now to FIG. 5, a second thermal oxide 501 is grown, consuming the nanocrystals 109. Mechanisms for thermal oxide growth are well understood. About 44% of underlying silicon is consumed to form a thermal silicon dioxide. At standard ambient temperatures (e.g., 68° C.), thermal oxide will grow to about 1 nm (10 Å, known as “native oxide”), consuming about 0.44 nm (4.4 Å) of underlying silicon. By elevating a processing temperature, for example, in a rapid thermal processor or diffusion furnace, the exposed nanocrystals 109 are entirely consumed. In one specific embodiment, an Applied Materials ISSG oxide chamber is used with a temperature of about 800° C.-900° C. for 10-30 seconds. Therefore, the second thermal oxide 501 is comprised of either consumed nanocrystals 109 or a partial consumption of the underlying polysilicon gate 311.

With reference to FIG. 6, the second thermal oxide 501 is anisotropically etched (e.g., by RIE), removing portions of the second thermal oxide 501 from any non-vertical surfaces (assuming the substrate is horizontal). Portions of the second thermal oxide 501 remaining on vertical surfaces (i.e., on a periphery of the polysilicon gate 311) form oxide spacers 601. The oxide spacers allow self-aligned dopant regions to be either implanted or diffused in subsequent processing steps (not shown). After the oxide spacers 601 have been formed, standard processing occurs to complete the nanocrystal memory device. A remaining portion of the first thermal oxide layer 105 allows electrons to tunnel from the nanocrystals 109 under applied voltage conditions as is known in the art.

Although the nanocrystal memory cell has been described in terms of general and specific exemplary embodiments, a skilled artisan will appreciate that other processes and techniques may be employed which are envisioned by a scope of the present invention. For example, there are frequently several techniques used for depositing a given film layer (e.g., chemical vapor deposition, plasma-enhanced vapor deposition, epitaxy, atomic layer deposition, etc.). Although not all techniques are amenable to all film types described herein, one skilled in the art will recognize that multiple methods for depositing a given layer and/or film type may be used. Additionally, the gate is defined in terms of a polycrystalline silicon. However, other types of polycrystalline semiconductors may readily be used and be within a contemplated scope of the present invention.

1. A method for forming a nanocrystal memory gate stack, comprising:
forming a first thermal oxide layer on a surface of a substrate;
forming a control layer dielectric over the first thermal oxide layer, the control layer dielectric containing a plurality of nanocrystals;
forming a polycrystalline gate over the control layer dielectric;
etching portions of the control layer dielectric that are not covered by the polycrystalline gate until a plurality of nanocrystals not located under the polycrystalline gate is exposed; and
consuming the exposed plurality of nanocrystals by employing a thermal oxidation process, the thermal oxidation process producing a second thermal oxide, a remaining plurality of nanocrystals forming a floating gate.

2. The method of claim 1 wherein the substrate is a silicon wafer.

3. The method of claim 1 wherein the polycrystalline gate is comprised of silicon.

4. The method of claim 1 wherein the control layer dielectric is comprised substantially of silicon dioxide.

5. The method of claim 1 wherein the plurality of nanocrystals are comprised of silicon.

6. The method of claim 1 further comprising anisotropically etching the second thermal oxide to form oxide spacers, the oxide spacers being formed on a periphery of the polycrystalline gate, the periphery of the polycrystalline gate being substantially normal to the surface of the substrate.

7. An electronic memory device, comprising:
a substrate;
a floating gate, the floating gate being formed by
(i) forming a control layer dielectric on a surface of a substrate, the control layer dielectric containing a plurality of nanocrystals;
(ii) forming a polycrystalline gate over the control layer dielectric;
(iii) etching portions of the control layer dielectric that are not covered by the polycrystalline gate until a plurality of nanocrystals that is not under the polycrystalline gate is exposed; and
(iv) consuming the exposed plurality of nanocrystals by employing a thermal oxidation process, the thermal oxidation process producing a second thermal oxide, a remaining the plurality of nanocrystals forming a floating gate;
a first thermal oxide layer, the first thermal oxide layer being configured to allow electrons to tunnel into the remaining plurality of nanocrystals, the remaining plurality of nanocrystals being separated from the substrate by the first thermal oxide layer; and
a control gate, the control gate being separated from the remaining plurality of nanocrystals in the floating gate by the control layer dielectric.

8. The electronic memory device of claim 7 wherein the substrate is a silicon wafer.

9. The electronic memory device of claim 7 wherein the polycrystalline gate is comprised of silicon.

10. The electronic memory device of claim 7 wherein the control layer dielectric is comprised substantially of silicon dioxide.

11. The electronic memory device of claim 7 wherein the plurality of nanocrystals are comprised of silicon.

12. The electronic memory device of claim 7, wherein the electronic memory device is an EEPROM cell.

13. The electronic memory device of claim 7, wherein the electronic memory device is a flash cell.

14. The electronic memory device of claim 7, wherein the thermal oxide layer is between 3 nm and 5 nm in thickness.

15. The electronic memory device of claim 7 further comprising oxide spacers, the oxide spacers being located on a periphery of the polycrystalline gate, the periphery of the polycrystalline gate being substantially normal to the surface of the substrate.

16. A method for forming a nanocrystal memory gate stack, comprising:
forming a first thermal oxide layer on a surface of a silicon substrate;
forming a control layer dielectric over the first thermal oxide layer, the control layer dielectric containing a plurality of silicon nanocrystals;
forming a polysilicon gate over the control layer dielectric;
etching portions of the control layer dielectric that are not covered by the polysilicon gate until a plurality of silicon nanocrystals not located under the polycrystalline gate is exposed; and
consuming the exposed plurality of silicon nanocrystals by employing a thermal oxidation process, the thermal oxidation process producing a second thermal oxide, a remaining plurality of silicon nanocrystals forming a floating gate.

17. The method of claim 16 wherein the control layer dielectric is comprised substantially of silicon dioxide.

18. The method of claim 16 further comprising anisotropically etching the second thermal oxide to form oxide spacers, the oxide spacers being formed on a periphery of the polycrystalline gate, the periphery of the polycrystalline gate being substantially normal to the surface of the substrate.
